(19) United States
(12) Patent Application Publication
(10) Pub. No.: US 2025/0204025 A1
(43) Pub. Date: Jun. 19, 2025

(54) SEMICONDUCTOR DEVICE

(71) Applicant: Renesas Electronics Corporation, Tokyo (JP)

(72) Inventors: Takayuki IGARASHI, Tokyo (JP); Yasutaka NAKASHIBA, Tokyo (JP)

(21) Appl. No.: 18/915,627

(22) Filed: Oct. 15, 2024

(30) Foreign Application Priority Data
Dec. 18, 2023 (JP) 2023-213011

(51) Int. Cl. H01L 27/06; H01L 23/525

(52) U.S. Cl. CPC H10D 84/40; H01L 23/5256

(57) ABSTRACT

A semiconductor device includes fuse circuits, and each of the fuse circuits includes fuse elements and cutting transistors. The fuse elements and the cutting transistors are arranged in a first direction of a first main surface of a semiconductor substrate, respectively, and each of the fuse elements is surrounded by each of deep trench isolation parts in plan view. In plan view, each of the cutting transistors is surrounded by each of power supply parts, and the power supply parts are integrally surrounded by the deep trench isolation part. The cutting transistors are formed in a well region, and each of the power supply parts has the same conductivity type as the well region and is formed in the well region.

### CROSS-REFERENCE TO RELATED APPLICATIONS

The disclosure of Japanese Patent Application No. 2023-213011 filed on Dec. 18, 2023, including the specification, drawings and abstract is incorporated herein by reference in its entirety.

### BACKGROUND

The present invention relates to a semiconductor device, for example, relates to a technique effective and applicable to a semiconductor devices including MISFETs and fuse elements.

Semiconductor devices incorporate various semiconductor elements such as Metal Insulator Semiconductor Field Effect Transistors (MISFETs). In some cases, fuse elements are also incorporated into semiconductor devices. For example, by providing fuse elements in semiconductor devices in advance and cutting the fuse elements as needed, it is possible to adjust circuit characteristics or eliminate faulty circuits. Fuse elements are cut by irradiating laser light or by melting through Joule heat by passing current.

There are disclosed techniques listed below.

### [Patent Document 1] Japanese Unexamined Patent Application Publication No. 2020-27852

Patent Document 1 discloses a technique for cutting fuse elements by passing current through fuse elements having a laminated structure including a silicon pattern and a metal silicide layer.

### SUMMARY

The inventors of the present application have identified the following issues in semiconductor devices having a plurality of fuse circuits, each of which includes a fuse element and a cutting transistor for passing current to the fuse element.

In the fuse circuit region of the semiconductor device, a plurality of fuse circuits are arranged. Each of the fuse circuits handles 1 bit of data. As semiconductor devices become more functional, the number of data (or bits) handled by a plurality of fuse circuits increases from tens of bits to hundreds of bits, resulting in an increase in the occupied area of the fuse circuit region. Therefore, a reduction in the occupied area of the fuse circuit region, that is, miniaturization of the semiconductor device, is required.

Other objects and novel characteristics will become apparent from the description of this specification and the accompanying drawings.

In one embodiment, the semiconductor device includes a plurality of fuse circuits, each of which includes a fuse element and a cutting transistor. The plurality of fuse elements and a plurality of cutting transistors are arranged in a first direction on a first main surface of the semiconductor substrate, and in plan view, each of the plurality of fuse elements is surrounded by respective first deep trench isolation parts. In plan view, each of the plurality of cutting transistors is surrounded by respective power supply parts, and the plurality of power supply parts are integrally surrounded by a second deep trench isolation part. The plurality of cutting transistors are formed in a well region, and each of the plurality of power supply parts has the same conductivity type as the well region and is formed in the well region.

According to one embodiment, the semiconductor device can be miniaturized.

### BRIEF DESCRIPTION OF THE DRAWINGS

FIG. 1 is a diagram showing a fuse circuit included in a semiconductor device of one embodiment.

FIG. 2 is a plan view of a main portion of the semiconductor device of one embodiment.

FIG. 3 is a plan view of the main portion of the semiconductor device of one embodiment.

FIG. 4 is a cross-sectional view of the semiconductor device along line A-A of FIG. 3.

FIG. 5 is a cross-sectional view of the semiconductor device along line B-B of FIG. 3.

FIG. 6 is a plan view of the main portion of the semiconductor device of one embodiment.

FIG. 7 is a plan view of the main portion of the semiconductor device of one embodiment.

FIG. 8 is a cross-sectional view of the semiconductor device along line C-C of FIG. 7.

FIG. 9 is a plan view of the main portion of the semiconductor device of the first modified example.

FIG. 10 is a plan view of the main portion of the semiconductor device of the second modified example.

FIG. 11 is a plan view of the main portion of the semiconductor device of the third modified example.

FIG. 12 is a plan view of the main portion of the semiconductor device of the third modified example.

FIG. 13 is a cross-sectional view of the semiconductor device along line D-D in FIG. 12.

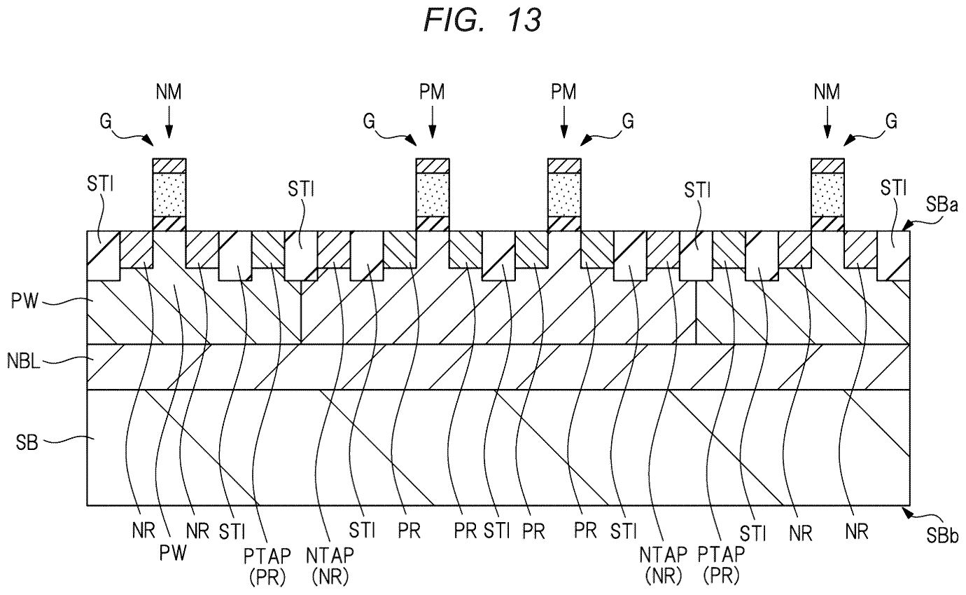

FIG. 14 is a plan view of the main portion of the semiconductor device of the comparative example.

FIG. 15 is a cross-sectional view of the semiconductor device along line E-E in FIG. 14.

FIG. 16 is a plan view of the main portion of the semiconductor device of first related technique.

FIG. 17 is a plan view of the main portion of the semiconductor device of second related technique.

FIG. 18 is a cross-sectional view of the main portion of the cutting transistor of second related technique.

FIG. 19 is a diagram showing the current-voltage characteristics of the cutting transistor of third related technique.

### DETAILED DESCRIPTION

In all the drawings for explaining the embodiment, the same components are designated by the same reference numerals, and the description thereof is omitted.

In the following embodiment, N-type means the N-type conductivity type, and P-type means the P-type conductivity type. Also, the P-type semiconductor region can be read as the P-type impurity region, and the N-type semiconductor region can be read as the N-type impurity region.

The X direction and the Y direction are along the first main surface of the semiconductor substrate and orthogonal to each other.

### EMBODIMENT

The semiconductor device in the present embodiment includes a fuse circuit, the fuse circuit includes a fuse element and a cutting transistor for passing current through the fuse element. The fuse element is cut by the Joule heat generated by the current flowing through the fuse element.

### Technical Problem of Related Technique

### First Related Technique

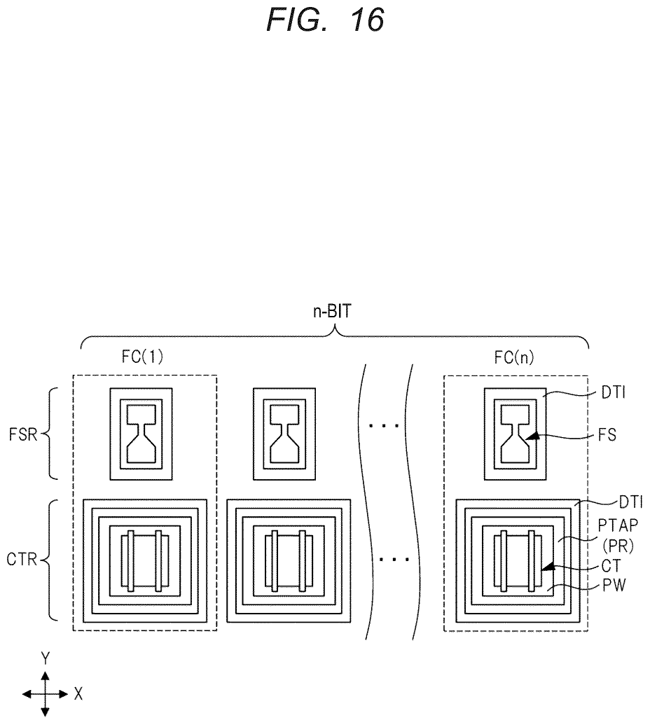

As shown in FIG. 16, the semiconductor device in first related technique includes a plurality of fuse circuits FC for handling n-bit data. A fuse circuit FC for handling 1-bit data includes a fuse element FS and a cutting transistor CT, and a plurality of fuse circuits FC for handling n-bit data are arranged, for example, in the X direction. n fuse elements FS and n cutting transistors CT are arranged in the X direction, respectively, and among them, one of the plurality of fuse elements FS and one of the plurality of cutting transistors CT are arranged in the Y direction.

In plan view, each of the n fuse elements FS is surrounded by a deep trench isolation part DTI. Each of the n cutting transistors CT is formed in each of the n P-type well regions PW, and in plan view, each of the n cutting transistors CT is surrounded by each of the n power supply parts PTAP. Furthermore, in plan view, each of the n power supply parts PTAP is surrounded by each of the n deep trench isolation parts DTI.

As the number of bits of data handled by the fuse circuit FC increases, the occupied area of the fuse circuit region expands, necessitating a reduction in the occupied area.

### Second Related Technique

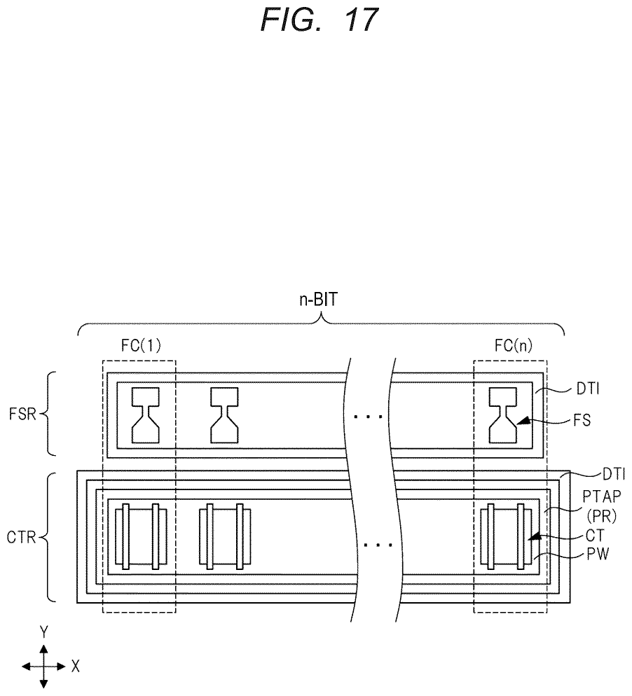

The second related technique is a structure that reduces the occupied area of the fuse circuit region in the first related technique. As shown in FIG. 17, the semiconductor device in the second related technique includes a plurality of fuse circuits FC for handling n-bit data, similar to the first related technique. In plan view, the n fuse elements FS are integrally surrounded by a deep trench isolation part DTI. The n cutting transistors CT are formed in a single P-type well region PW. And in plan view, the n cutting transistors CT are integrally surrounded by a single power supply part PTAP, and the surroundings of the power supply part PTAP are surrounded by a single deep trench isolation part DTI. Compared to the first related technique, the second related technique can omit the deep trench isolation part DTI between two adjacent fuse elements FS, and further, can omit the power supply part PTAP and the deep trench isolation part DTI between two adjacent cutting transistors CT. Therefore, it is possible to reduce the occupied area of the fuse circuit region in the X direction.

Upon examination by the inventors of the present application, the following problems were identified in second related technique. First, in plan view, n fuse elements FS are integrally surrounded by a deep trench isolation part DTI, and there is no deep trench isolation part DTI between two adjacent fuse elements FS. The fuse elements FS are formed on a shallow trench isolation part STI, which will be described later. The fuse elements FS are cut by Joule heat generated by the current flowing through the fuse elements FS. Upon cutting, it was confirmed that cracks occur in the shallow trench isolation part STI under the fuse elements FS, and these cracks extend to the adjacent fuse elements FS. As will be described later, the fuse elements FS have a laminated structure including a polysilicon layer and a silicide layer. When the silicide layer of the cut fuse element FS extends in the crack to reach the adjacent fuse elements FS, the two adjacent fuse elements FS short-circuit. When the two adjacent fuse elements FS short-circuit, despite one of the fuse elements FS being cut, it is mis-decided that the fuse elements FS are not cut, leading to a malfunction of the fuse circuit FC.

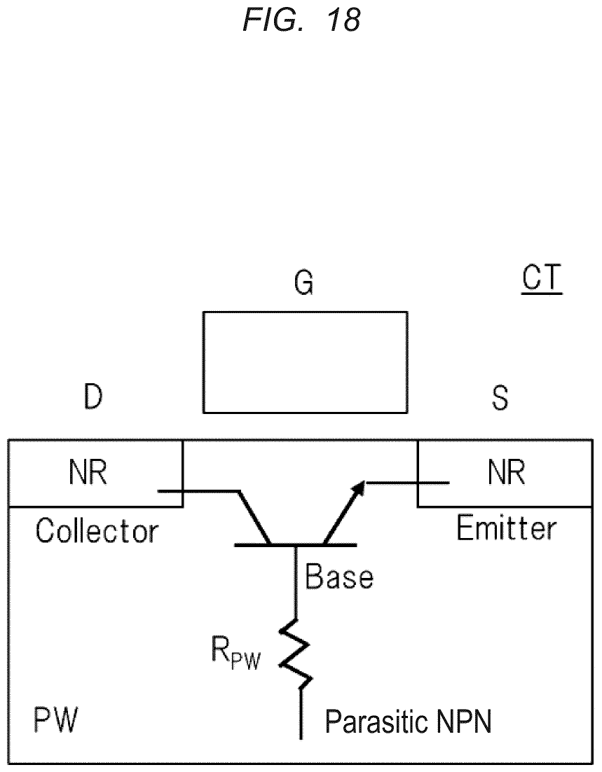

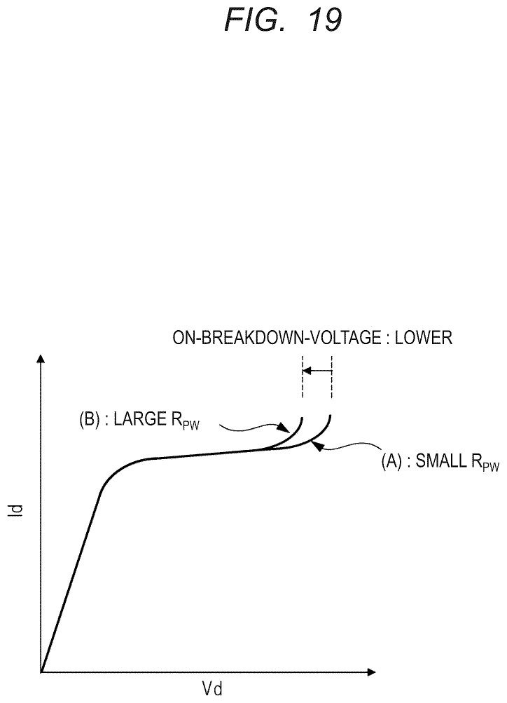

Furthermore, as shown in FIG. 17, n cutting transistors CT are formed in a P-type well region PW and are integrally surrounded by a power supply part PTAP in plan view. A cutting transistor CT handling the data of the 1st bit or the n-th bit, compared to a cutting transistor CT handling the data of the n/2 bit, is positioned further away from the power supply part PTAP in the X direction, resulting in a larger parasitic resistance RPW of the P-type well region PW. As shown in FIG. 18, in the cutting transistor CT, there is a possibility that a parasitic NPN transistor, which includes a drain acting as a collector, a source acting as an emitter, and a P-type well region PW acting as a base, turns on. And, as shown in FIG. 19, the larger the parasitic resistance RPW of the P-type well region PW, the lower the on-voltage of the parasitic NPN transistor, and the parasitic NPN transistor turns on at a lower drain voltage. Then, a large current flow between the drain and the source of the cutting transistor CT, causing the cutting transistor CT to be destroyed. As a result, a malfunction of the fuse circuit FC occurs.

Therefore, the technical problem derived from first related technique and a second related technique are to reduce the occupied area of the fuse circuit region. Furthermore, the technical problem is to prevent malfunctions of the fuse circuit FC caused by defects in the fuse elements FS and the cutting transistors CT.

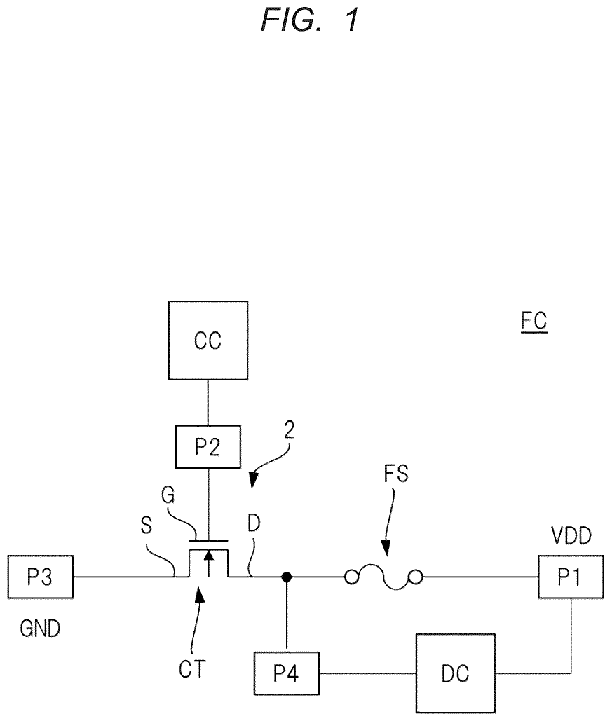

Structure of Semiconductor Device As shown in FIG. 1, a fuse circuit FC for handling 1-bit data includes a fuse element FS, a cutting transistor CT, a control circuit CC, and a decision circuit DC. The fuse element FS and the cutting transistor CT are connected in series between a power supply potential VDD and a reference potential GND. One end of the fuse element FS is connected to terminal P1, and terminal P1 is connected to the power supply potential VDD. The other end of the fuse element FS is connected to the drain D of the cutting transistor CT. The source of the cutting transistor CT is connected to terminal P3, and terminal P3 is connected to the reference potential GND. The gate G of the cutting transistor

CT is connected to terminal P2, and the control circuit CC is connected to terminal P2. The other end of the fuse element FS and the drain D of the cutting transistor CT are connected to terminal P4, and a decision circuit DC is connected between terminal P4 and terminal P1.

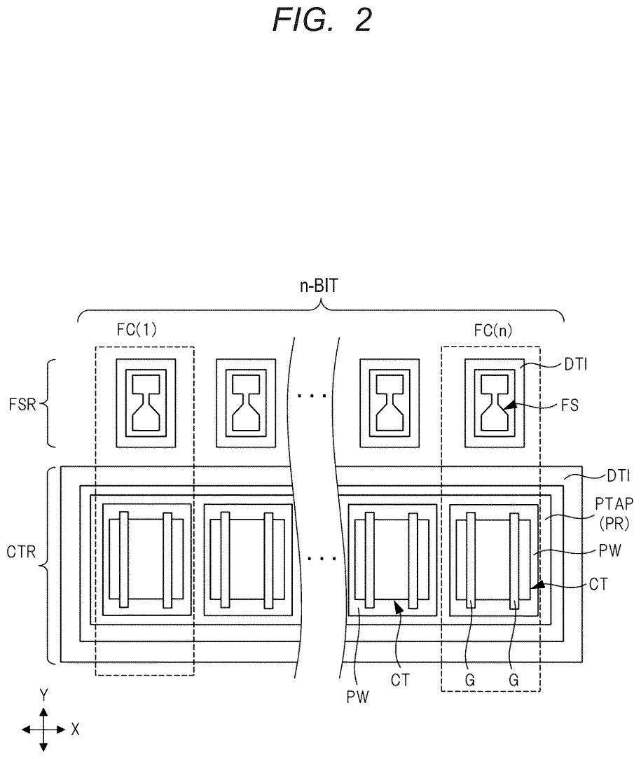

As shown in FIG. 2, a plurality of fuse circuits FC for handling n-bit data are arranged in the X direction. In the fuse element region FSR, n fuse elements FS are arranged in a row in the X direction. In the Y direction, in the cutting transistor region CTR adjacent to the fuse element region FSR, n cutting transistors CT are arranged in a row in the X direction. Each of the cutting transistors CT is configured by a plurality of MISFETs connected in parallel. Furthermore, each of the cutting transistors CT includes a plurality of gates G extending in the Y direction, and the plurality of gates G are connected in parallel with each other.

In plan view, each of the n fuse elements FS is surrounded by a deep trench isolation part DTI. The n cutting transistors CT are formed integrally in a P-type well region. In plan view, each of the n cutting transistors CT is surrounded by a power supply tap PTAP. Furthermore, in plan view, the n cutting transistors CT and the n power supply parts PTAP are integrally surrounded by a deep trench isolation part DTI. The deep trench isolation part DTI includes two X parts extending in the X direction and two Y parts extending in the Y direction, and the two X parts and the two Y parts form a rectangular frame.

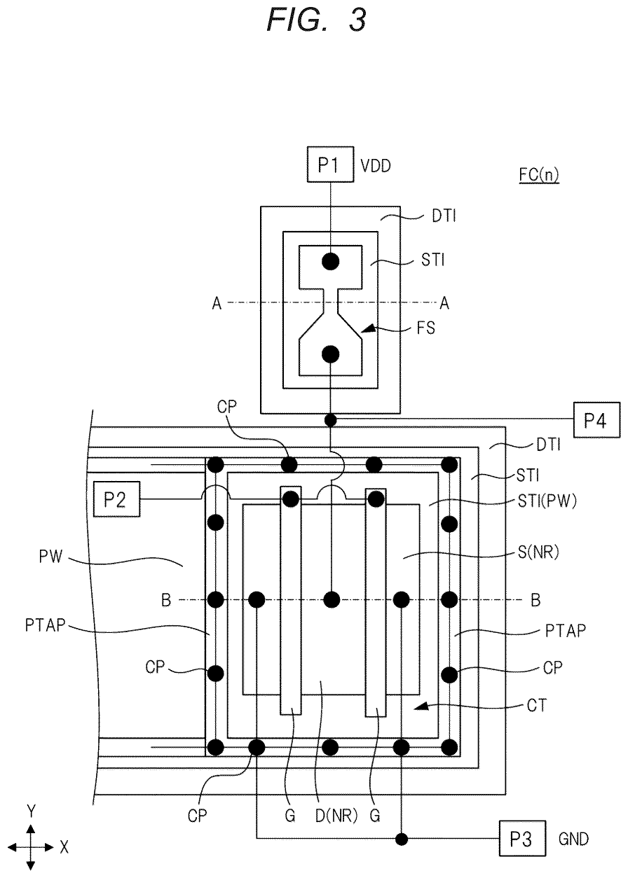

FIG. 3 is a plan view of the fuse element FS and the cutting transistor CT configuring the fuse circuit FC. FIG. 3 shows, as an example, one fuse circuit FC, and each of the plurality of fuse circuits FC has a similar structure. However, in plan view, the part of the deep trench isolation part DTI extending in the Y direction does not exist between two adjacent cutting transistors CT. The connection between the fuse element FS and the cutting transistor CT is as described in FIG. 1.

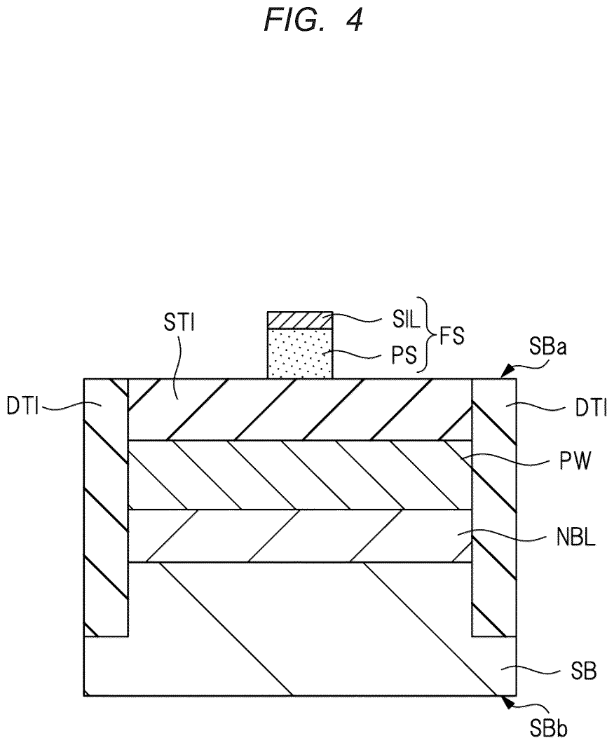

As shown in FIG. 4, the fuse element FS includes a laminated structure including a polycrystalline silicon layer PS and a silicide layer SIL arranged on the polycrystalline silicon layer PS. The fuse element FS is formed on a shallow trench isolation part STI formed on a first main surface SBa of a semiconductor substrate SB. In a direction orthogonal to the first main surface SBa of the semiconductor substrate SB, a P-type well region PW and an N-type buried semiconductor layer NBL are sequentially formed under the shallow trench isolation part STI. The second main surface SBb of the semiconductor substrate SB is located on the opposite side of the first main surface SBa. As can be seen from FIGS. 3 and 4, in plan view, the shallow trench isolation part STI, the P-type well region PW, and the N-type buried semiconductor layer NBL in the formation region of the fuse element FS are surrounded by a deep trench isolation part DTI. The depth of the deep trench isolation part DTI from the first main surface SBa is greater than the depth of the shallow trench isolation part STI from the first main surface SBa. Therefore, the shallow trench isolation part STI in the region where the fuse element FS handling the data of the n-th bit is formed and the shallow trench isolation part STI in the region where the fuse element FS handling the data of the (n−1)-th bit is formed are separated by the deep trench isolation part DTI. In other words, two adjacent shallow trench isolations STI are separated by the deep trench isolation part DTI. Also, two adjacent P-type well regions PW and two adjacent N-type buried semiconductor layers NBL are separated by the deep trench isolation part DTI. Both the shallow trench isolation part STI and the deep trench isolation part DTI are insulating films, including a silicon oxide film or a silicon nitride film. An N-type well region NW may be used instead of the P-type well region PW. When using the N-type well region NW, it is not necessary to form the N-type buried semiconductor layer NBL.

As shown in FIG. 3, the cutting transistor CT includes a plurality of gates G, and the plurality of gates G are connected to each other. Each of the plurality of gates G has a predetermined width in the X direction and extends in the Y direction. The cutting transistor CT has a source S and a drain D, and in plan view, the gate G is arranged between the source S and the drain D. In other words, the cutting transistor CT is configured by a plurality of N-type MISFETs (NM) connected in parallel. Thus, the mutual conductance of the cutting transistor CT is improved, and a large current can flow through the fuse element FS. FIG. 3 shows an example where the cutting transistor CT is configured by two N-type MISFETs (NM).

Furthermore, in plan view, the cutting transistor CT configuring the fuse circuit FC handling one bit of data is surrounded by a power supply part PTAP. On the power supply part PTAP, a plurality of connection parts CP are arranged in the X and Y directions, and the power supply part PTAP is electrically connected to the reference potential GND via each of the plurality of connection parts CP.

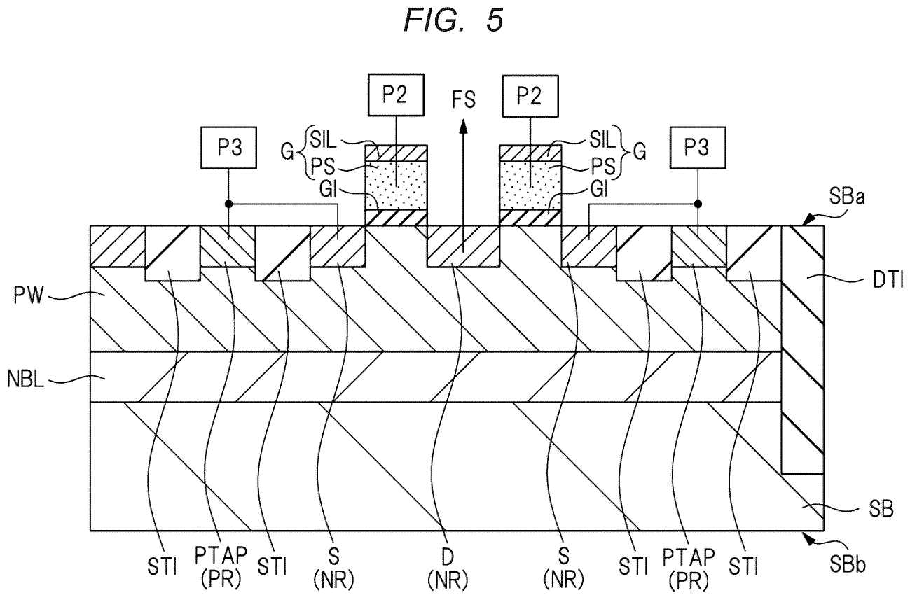

As shown in FIG. 5, the cutting transistor CT is formed in a P-type well region PW. The n cutting transistors CT, which handle n bits of data and are included in a plurality of fuse circuits FC, are formed in a single P-type well region PW in plan view (refer to FIG. 2). In the depth direction of the semiconductor substrate SB, an N-type buried semiconductor layer NBL is formed under the P-type well region PW. As shown in FIG. 2, in plan view, the P-type well region PW is surrounded by a deep trench isolation part DTI. As can be seen from FIGS. 2 and 5, in plan view, the N-type buried semiconductor layer NBL is also surrounded by the deep trench isolation part DTI. That is, in plan view, the P-type well region PW, in which the n cutting transistors CT are formed, is electrically isolated from the surrounding P-type well region PW mentioned above.

The cutting transistor CT has a gate insulating film GI formed on the first main surface SBa, a gate G formed on the gate insulating film GI, and a source S and a drain D formed in the P-type well region PW. The gate G has a laminated structure including a polysilicon layer PS and a silicide layer SIL formed on the polysilicon layer PS. The source S and the drain D are each an N-type semiconductor region NR.

The power supply part PTAP is configured by a P-type semiconductor region PR, and the P-type semiconductor region PR is formed in a P-type well region PW. That is, the power supply part PTAP has a P-type conductivity and is formed in the P-type well region PW. As shown in FIG. 3, the power supply part PTAP includes two X portions extending in the X direction and two Y portions extending in the Y direction, and the two X portions and the two Y portions configure a rectangular frame. In plan view, the cutting transistor CT is surrounded by the rectangular frame. Also, in plan view, in the two frames surrounding each of the two adjacent cutting transistors CT, the two Y portions located between the two adjacent cutting transistors CT are integrated. That is, one Y portion is arranged between the two adjacent cutting transistors CT. And, a reference potential GND is supplied to the P-type well region PW via the P-type semiconductor region PR, which is the power supply part PTAP.

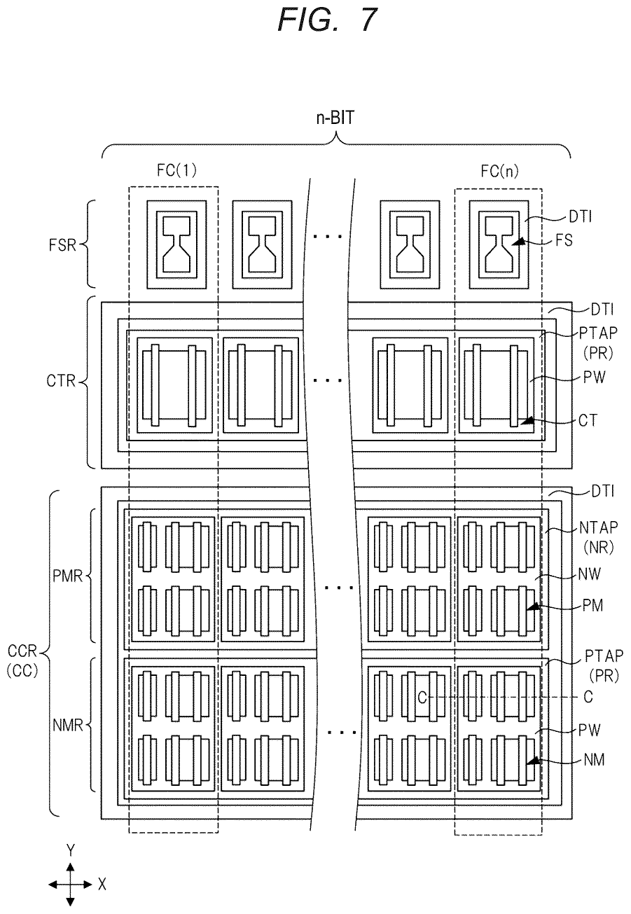

As shown in FIG. 7, in the Y direction, the fuse element region FSR, the cutting transistor region CTR, and the control circuit region CCR are arranged in this order. In the Y direction, the cutting transistor region CTR is arranged between the fuse element region FSR and the control circuit region CCR. The control circuit region CCR includes a PMIS region PMR and an NMIS region NMR. To configure a fuse circuit FC that handles 1-bit data, a plurality of P-type MISFETs (PM) are arranged in the PMIS region PMR, and a plurality of N-type MISFETs (NM) are arranged in the NMIS region NMR. In plan view, a plurality of P-type MISFETs (PM) surrounded by one power supply part NTAP configure one block, and a plurality of N-type MISFETs (NM) surrounded by one power supply part PTAP configure one block. In the PMIS region PMR, a plurality of P-type MISFETs (PM) included in each block are integrally surrounded by the power supply part NTAP. Similarly, in the NMIS region NMR, in plan view, a plurality of N-type MISFETs (NM) included in each block are integrally surrounded by the power supply part PTAP. The power supply part NTAP includes two X portions extending in the X direction and two Y portions extending in the Y direction, and the two X portions and the two Y portions configure a rectangular frame.

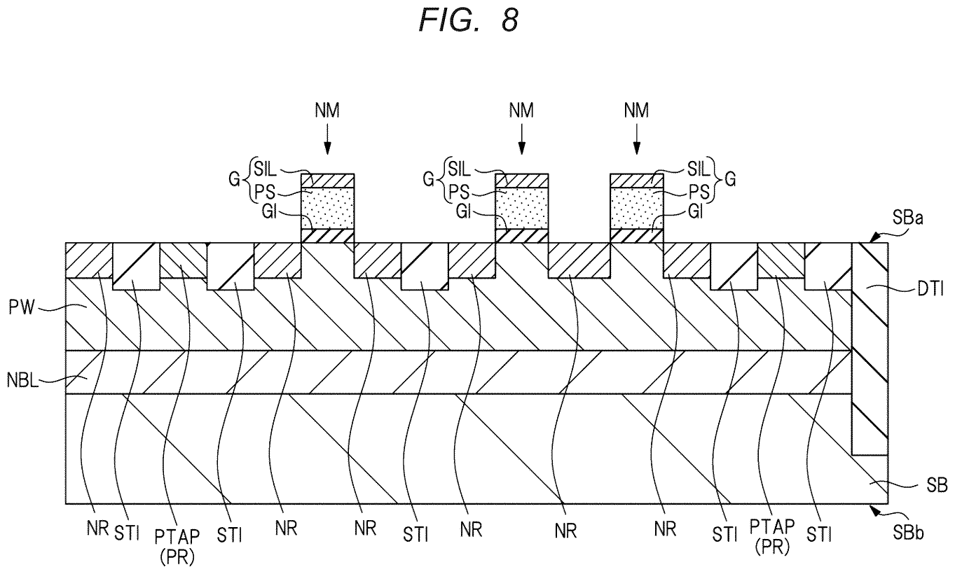

A plurality of P-type MISFETs (PM) included in n blocks are formed in a single N-type well region NW. Similarly, a plurality of N-type MISFETs (NM) included in n blocks are formed in a single P-type well region PW. As shown in FIG. 8, the power supply part PTAP is configured by a P-type semiconductor region PR, and the P-type semiconductor region PR is formed in the P-type well region PW. As shown in FIG. 7, in plan view, the plurality of N-type MISFETs (NM) included in each block are integrally surrounded by a P-type semiconductor region PR. Furthermore, the power supply part NTAP is configured by an N-type semiconductor region NR, and the N-type semiconductor region NR is formed in the N-type well region NW. As shown in FIG. 7, in plan view, the plurality of P-type MISFETs (PM) included in each block are integrally surrounded by an N-type semiconductor region NR. The P-type well region PW is connected to the reference potential GND via the P-type semiconductor region PR, which is the power supply part PTAP, and the N-type well region NW is connected to the power supply potential VDD via the N-type semiconductor region NR, which is the power supply part NTAP.

Furthermore, the plurality of P-type MISFETs (PM) included in n blocks, n power supply parts NTAP, the plurality of N-type MISFETs (NM) included in n blocks, and n power supply parts PTAP are, in plan view, integrally surrounded by a deep trench isolation part DTI.

It should be noted that, in FIG. 7, although n power supply parts NTAP are arranged in the NMIS region NMR, as a modified example of FIG. 7, all N-type MISFETs (NM) arranged in the NMIS region NMR may be surrounded by a single power supply part PTAP in plan view. Furthermore, all P-type MISFETs (PM) arranged in the PMIS region PMR may be surrounded by a single power supply part NTAP in plan view.

### Characteristics of Semiconductor Device

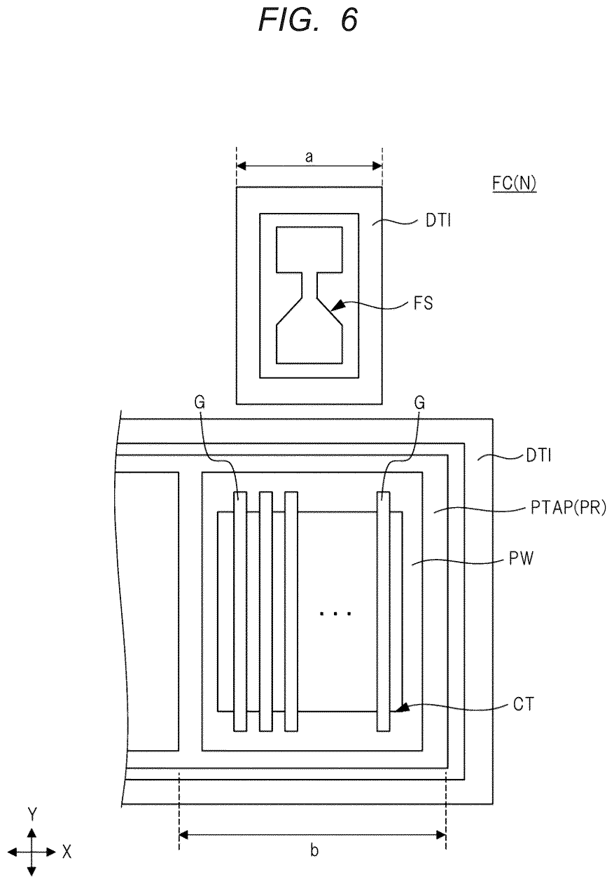

As shown in FIG. 2, by surrounding each of the n fuse elements FS with a deep trench isolation part DTI in plan view, it is possible to prevent malfunction of the aforementioned fuse circuit FC. That is, it is possible to prevent malfunction of the fuse circuit FC caused by a short circuit between two adjacent fuse elements FS. Even with the structure where each individual fuse element FS is surrounded by a deep trench isolation part DTI in plan view, the formation region of the fuse circuit FC that handles 1-bit data in the X-direction does not expand. This is because, as shown in FIG. 6, in the X-direction, the outer dimension b of the power supply part PTAP surrounding the cutting transistor CT in plan view is larger than the outer dimension a of the deep trench isolation part DTI surrounding the fuse element FS.

As described using FIGS. 2, 3, and 5, n cutting transistors CT are formed in a single P-type well region PW, and in plan view, each of the cutting transistors CT is surrounded by a power supply part PTAP. As a result, it is possible to reduce the parasitic resistance RPW of the P-type well region PW in the region where each of the cutting transistors CT is formed, compared to the third related technique, and prevent the destruction of the cutting transistor CT caused by the turning on of the parasitic NPN transistor. Furthermore, since the parasitic resistance RPW of the P-type well region PW in the region where each of the cutting transistors CT is formed can be made uniform, the ON-breakdown-voltage O cutting transistors CT can be made constant, regardless of the placement position of the cutting transistor CT. Therefore, it is possible to prevent the destruction caused by the turning on of the parasitic NPN transistor in the n cutting transistors CT. In other words, it is possible to prevent the malfunction of the fuse circuit FC.

Moreover, in plan view, an N-type buried semiconductor layer NBL is provided under the P-type well region PW where the n cutting transistors CT are formed, and in plan view, the P-type well region PW and the buried semiconductor layer NBL are surrounded by a deep trench isolation part DTI. This allows preventing electrical interference between the P-type well region PW where the n cutting transistors CT are formed and the surrounding P-type well regions PW in plan view.

Additionally, by surrounding the n cutting transistors CT and the n power supply parts PTAT integrally with the deep trench isolation part DTI in plan view, it is possible to reduce the formation region of a plurality of fuse circuits FC handling n-bit data in the X direction, compared to the first related technique.

Furthermore, in the control circuit region CCR, by surrounding a plurality of N-type MISFETs (NM) included in n blocks and the n power supply parts PTAP integrally with the deep trench isolation part DTI in plan view, it is possible to downsize the control circuit region CCR of a plurality of fuse circuits FC handling n-bit data in the X direction.

Similarly, by surrounding a plurality of P-type MISFETs (PM) included in n blocks and the n power supply parts NTAP integrally with the deep trench isolation part DTI in plan view, it is possible to downsize the control circuit region CCR of a plurality of fuse circuits FC handling n-bit data in the X direction.

As shown in FIG. 7, a plurality of N-type MISFETs (NM) included in n blocks are formed in a single P-type well region PW, and in plan view, a plurality of N-type MISFETs (NM) included in each block are surrounded by a power supply part PTAP. As a result, in each block, it is possible to reduce the parasitic resistance RPW of the P-type well region PW and prevent the destruction of the N-type MISFET (NM) caused by the turning on of the parasitic NPN transistor. Furthermore, since the parasitic resistance RPW of the P-type well region PW in each block can be made uniform, it is possible to prevent the destruction of the N-type MISFET (NM) caused by the turning on of the parasitic NPN transistor, regardless of placement position of the block. In other words, it is possible to prevent the malfunction of the control circuit included in the fuse circuit FC.

Furthermore, in n blocks, an N-type buried semiconductor layer NBL is provided under the P-type well region PW, and in plan view, the P-type well region PW and the buried semiconductor layer NBL are surrounded by a deep trench isolation part DTI. This prevents electrical interference between the P-type well region PW included in the control circuit region CCR and the P-type well region PW in other regions.

Furthermore, in plan view, by surrounding the PMIS region PMR and the NMIS region NMR included in the control circuit region CCR integrally with the deep trench isolation part DTI, the control circuit region CCR can be downsized.

### First Modified Example

The first modified example relates to the control circuit region CCR of the aforementioned embodiment.

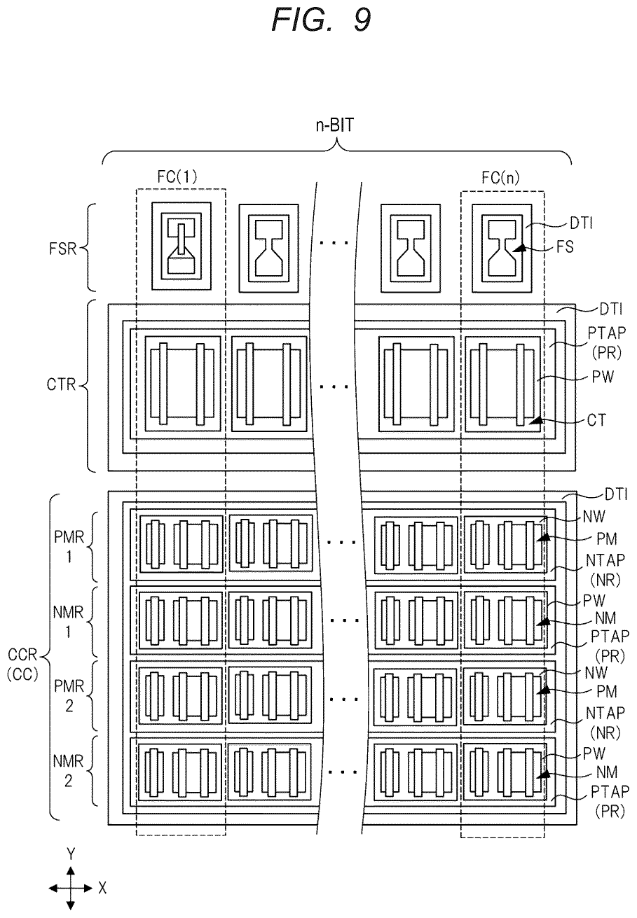

As shown in FIG. 9, the control circuit region CCR includes a PMIS region PMR1 and a PMIS region PMR2, as well as an NMIS region NMR1 and an NMIS region NMR2. The PMIS region PMR1 and the PMIS region PMR2 have similar structures to each other, and the NMIS region NMR1 and the NMIS region NMR2 have similar structures to each other.

The NMIS region NMR1 includes one P-type well region PW and n power supply parts PTAP. In plan view, a plurality of N-type MISFETs (NM) are formed in the region surrounded by the power supply part PTAP. Furthermore, in plan view, the plurality of N-type MISFETs (NM) surrounded by the power supply part PTAP configure a block. The NMIS region NMR1 includes n blocks. The plurality of N-type MISFETs (NM) included in the n blocks are formed in one P-type well region PW.

The PMIS region PMR1 includes one N-type well region NW and n power supply parts NTAP. In plan view, a plurality of P-type MISFETs (PM) are formed in the region surrounded by the power supply part NTAP. Furthermore, in plan view, the plurality of P-type MISFETs (PM) surrounded by the power supply part NTAP configure a block. The PMIS region PMR1 includes n blocks. The plurality of P-type MISFETs (PM) included in the n blocks are formed in one N-type well region NW.

The control circuit region CCR of the embodiment is formed of one PMIS region PMR and one NMIS region NMR, whereas in the first modified example, the control circuit region CCR is formed of the PMIS region PMR1, the PMIS region PMR2, the NMIS region NMR1 and the NMIS region NMR2. The first modified example allows for a reduction in the region of the P-type well region PW in each block in the control circuit region CCR compared to the embodiment. That is, it allows for a reduction in the parasitic resistance RPW of the P-type well region PW in each block in the control circuit region CCR. Therefore, it is possible to improve the ON-breakdown-voltage of the N-type MISFET (NM) in each block and prevent the destruction of the N-type MISFET (NM) caused by the turning on of the parasitic NPN transistor.

### Second Modified Example

The second modified example is an example in which a decision circuit region DCR is added to the first modified example.

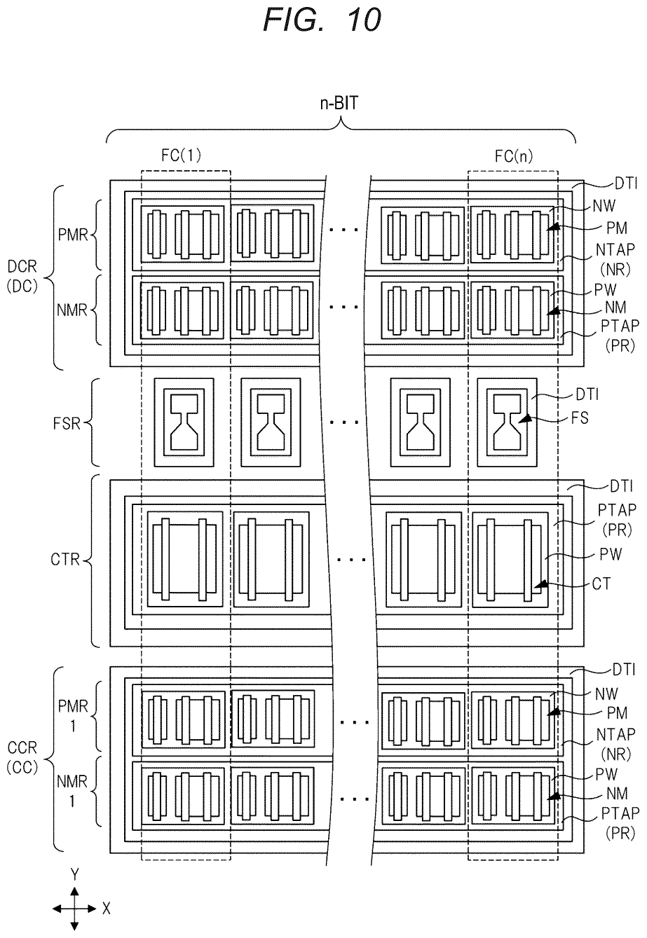

As shown in FIG. 10, in the Y direction, the fuse element region FSR is arranged between the decision circuit region DCR and the cutting transistor region CTR. The decision circuit region DCR includes a PMIS region PMR and an NMIS region NMR. In the control circuit region CCR, only the PMIS region PMR1 and the NMIS region NMR1 are shown, and the PMIS region PMR2 and the NMIS region NMR2 are omitted.

The NMIS region NMR includes one P-type well region PW and n power supply parts PTAP. In plan view, a plurality of N-type MISFETs (NM) are formed in the region surrounded by the power supply part PTAP. Furthermore, in plan view, the plurality of N-type MISFETs (NM) surrounded by the power supply part PTAP configure a block. The NMIS region NMR includes n blocks. The plurality of N-type MISFETs (NM) included in the n blocks are formed in one P-type well region PW.

The PMIS region PMR includes one N-type well region NW and n power supply parts NTAP. In plan view, a plurality of P-type MISFETs (PM) are formed in the region surrounded by the power supply part NTAP. Furthermore, in plan view, the plurality of P-type MISFETs (PM) surrounded by the power supply part NTAP configure a block. The PMIS region PMR includes n blocks.

In the second modified example, in the decision circuit region DCR, in plan view, each of the n blocks is surrounded by the power supply part PTAP. Therefore, it is possible to reduce the parasitic resistance RPW of the P-type well region PW in each block. Consequently, it is possible to improve the ON-breakdown-voltage of the N-type MISFET (NM) in each block and prevent the destruction of the N-type MISFET (NM) caused by the turning on of the parasitic NPN transistor.

Moreover, by placing the decision circuit region DCR adjacent to the fuse element region FSR, it becomes easier to arrange the wiring connecting the decision circuit DC and the fuse element FS. Also, it is possible to reduce the length of the wiring connecting the decision circuit DC and the fuse element FS.

### Third Modified Example

The third modified example is a modified example related to the control circuit region CCR of the aforementioned second modified example.

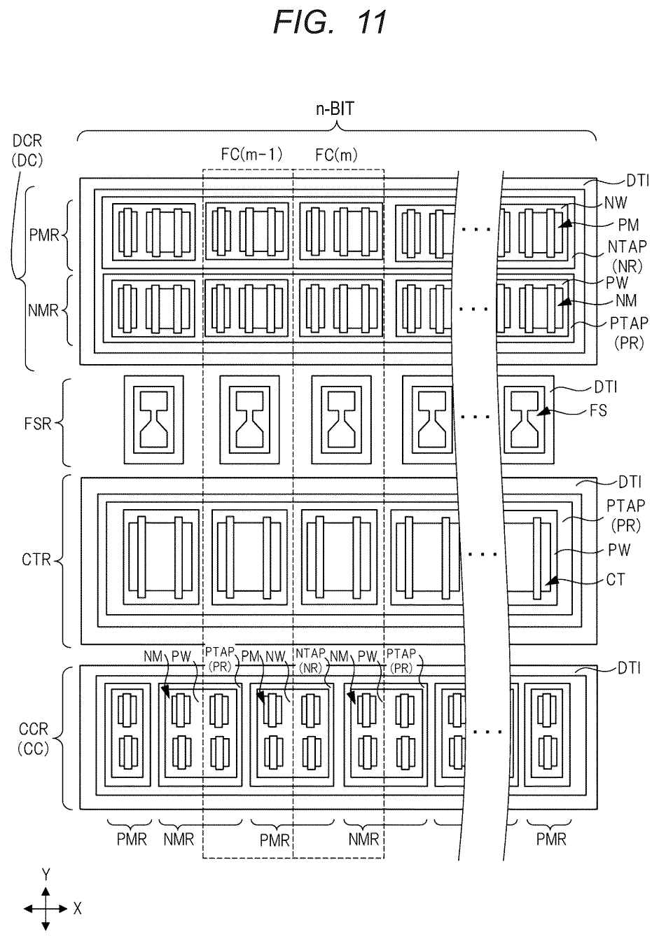

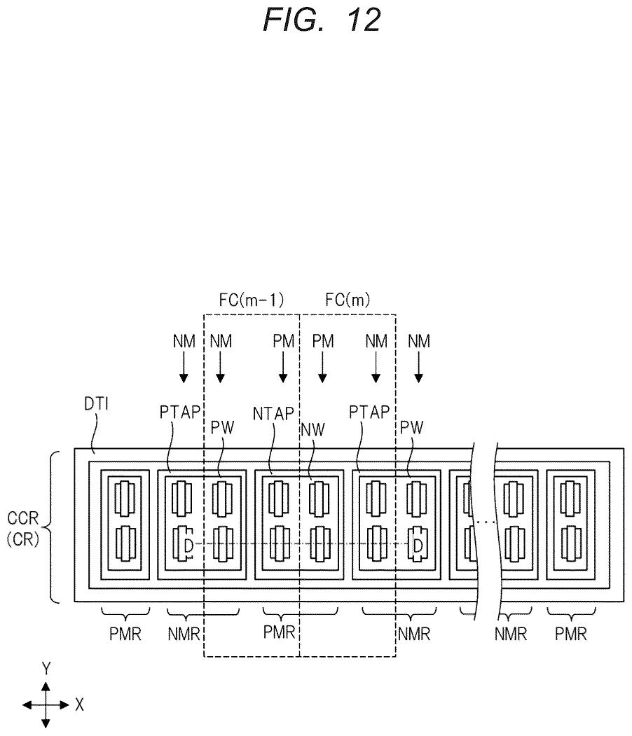

As shown in FIGS. 11 and 12, the control circuit region CCR includes a PMIS region PMR and an NMIS region NMR. In the X direction, the PMIS region PMR and the NMIS region NMR are alternately arranged.

The PMIS region PMR includes one N-type well region NW and one power supply part NTAP. In plan view, a plurality of P-type MISFETs (PM) are formed in the region surrounded by the power supply part NTAP. The control circuit CC of the fuse circuit FC, which handles 2-bit data, is configured using the aforementioned a plurality of P-type MISFETs (PM).

The NMIS region NMR includes a single P-type well region PW and a single power supply part PTAP. In plan view, a plurality of N-type MISFETs (NM) are formed in the region surrounded by the power supply part PTAP. The control circuit CC of the fuse circuit FC, which handles 2-bit data, is configured using the aforementioned a plurality of N-type MISFETs (NM).

As shown in FIGS. 11 and 12, the control circuit CC of the fuse circuit FC, which handles the data of the m-th bit, is configured using a plurality of P-type MISFETs (PM) that are part of the PMIS region PMR. Furthermore, the control circuit CC of the fuse circuit FC, which handles the data of the m-th bit, is also configured using a plurality of N-type MISFETs (NM) that are part of the NMIS region NMR, adjacent to the right side of the aforementioned PMIS region PMR.

The control circuit CC of the fuse circuit FC, which handles the data of the (m−1)-th bit, is configured using a plurality of P-type MISFETs (PM) that are another part of the aforementioned PMIS region PMR. Furthermore, the control circuit CC of the fuse circuit FC, which handles the data of the (m−1)-th bit, is also configured using a plurality of N-type MISFETs (NM) that are part of the NMIS region NMR, adjacent to the left side of the aforementioned PMIS region PMR. However, at the ends in the X direction in the PMIS region PMR or NMIS region NMR, there may be only P-type MISFETs (PM) or N-type MISFETs (NM) for configuring the control circuit CC of the fuse circuit FC that handles 1-bit data, hence 2≤m≤(n−1). m is a natural number.

As shown in FIGS. 11 and 12, a plurality of control circuits CC, in the X direction, include the (m−1)-th control circuit CC and the m-th control circuit CC, which are adjacent to each other. The (m−1)-th control circuit CC handles the data of the (m−1)-th bit, and the m-th control circuit CC handles the data of the m-th bit. In the adjacent PMIS region PMR and NMIS region NMR, parts of the plurality of P-type MISFETs (PM) are connected to the m-th control circuit CC, and other parts of the plurality of P-type MISFETs (PM) are connected to the (m−1)-th control circuit CC. Furthermore, parts of the plurality of N-type MISFETs (NM) are connected to the m-th control circuit CC. The parts of the plurality of P-type MISFETs (PM) connected to the m-th control circuit CC and the other parts of the plurality of P-type MISFETs (PM) connected to the (m−1)-th control circuit CC are surrounded by a common power supply body NTAP in plan view.

Thus, in the X direction, parts and other parts of the plurality of P-type MISFETs (PM) connected to two adjacent control circuits CC are placed in a single PMIS region PMR. By placing parts and other parts of the plurality of P-type MISFETs (PM) commonly in a single N-type well region NW and surrounding them with a single power supply part NTAP, the occupied area of the control circuit region CCR in the X direction can be reduced.

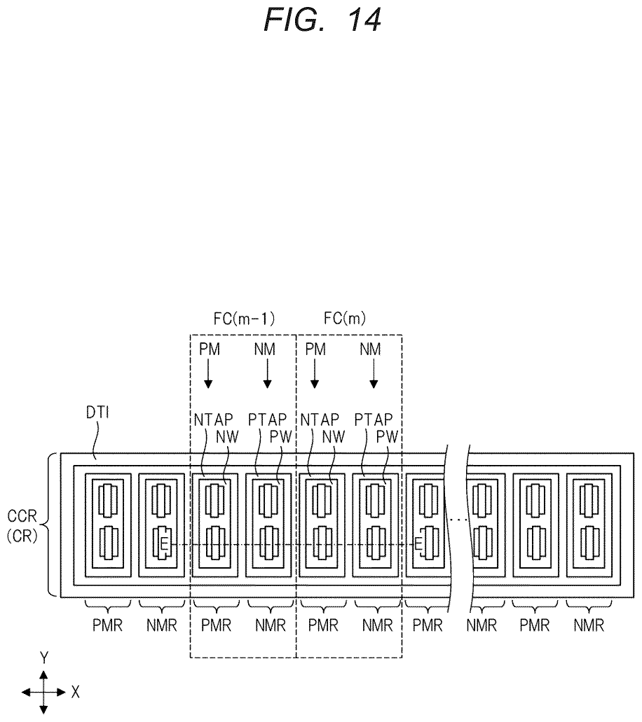

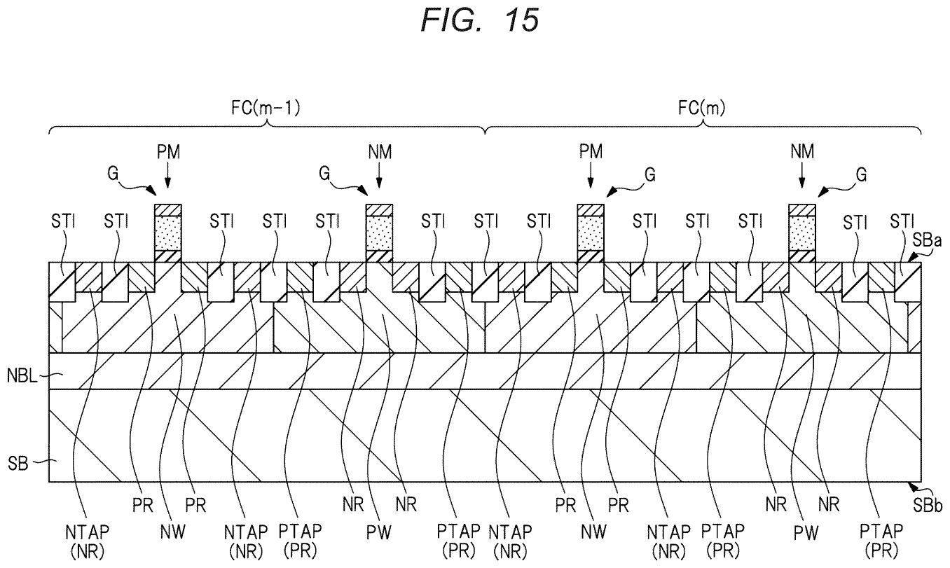

As shown in FIGS. 14 and 15, the control circuit region CCR of the comparative example is also arranged in the X direction, with the PMIS region PMR and the NMIS region NMR alternately arranged. A plurality of control circuits CC, in the X direction, include a (m−1)-th control circuit CC and an m-th control circuit CC, which are adjacent to each other. For configuring the (m−1)-th control circuit CC, the PMIS region PMR and the NMIS region NMR are arranged in the control circuit region CCR. Furthermore, for configuring the m-th control circuit CC, the PMIS region PMR and the NMIS region NMR are arranged in the control circuit region CCR. That is, in the X direction, the PMIS region PMR, the NMIS region NMR, the PMIS region PMR, and the NMIS region NMR are arranged in this order. And a plurality of P-type MISFETs (PM) included in the PMIS region PMR are formed in the N-type well region NW in plan view and are surrounded by the power supply part NTAP. Similarly, a plurality of N-type MISFETs (NM) included in the NMIS region NMR are formed in the P-type well region PW in plan view and are surrounded by the power supply part PTAP.

Thus, in the X direction, a plurality of P-type MISFETs (PM) connected to two adjacent control circuits CC are independently arranged in two N-type well regions NW and are surrounded by two power supply parts NTAP. Therefore, the semiconductor device of the comparative example, compared to the third modified example of the semiconductor device, has an increased occupied area of the control circuit region CCR in the X direction.

As described above, the invention made by the present inventor has been specifically described based on the embodiment, but it goes without saying that the present invention is not limited to the described embodiment and can be modified in various ways without departing from the gist thereof.

What is claimed is:

1. A semiconductor device comprising:
a semiconductor substrate having a first main surface and a second main surface located on the opposite side of the first main surface;
a plurality of fuse elements formed on the first main surface of the semiconductor substrate and arranged in a first direction;
a plurality of cutting transistors formed on the first main surface of the semiconductor substrate, the plurality of cutting transistors being adjacent to the plurality of fuse elements in a second direction orthogonal to the first direction, and the plurality of cutting transistors being arranged in the first direction;
a plurality of fuse circuits;
a plurality of first deep trench isolation parts formed in the semiconductor substrate;
a plurality of first power supply parts formed in the semiconductor substrate;
a second deep trench isolation part formed in the semiconductor substrate, the second deep trench isolation part surrounding the plurality of first power supply parts in plan view; and
a first well region of a first conductive type extending from the first main surface of the semiconductor substrate toward the second main surface,
wherein, in plan view, each of the plurality of first deep trench isolation parts surrounds each of the plurality of fuse elements,
wherein, in plan view, each of the plurality of first power supply parts surrounds each of the plurality of cutting transistors,
wherein each of the plurality of fuse circuits includes each of the plurality of cutting transistors and each of the plurality of fuse elements,
wherein each of the plurality of cutting transistors comprises:
a gate formed on the semiconductor substrate;
a source of a second conductive type different from the first conductive type formed in the semiconductor substrate; and
a drain of the second conductive type formed in the semiconductor substrate,
wherein, in plan view, the plurality of cutting transistors are formed in the first well region, and
wherein each of the plurality of first power supply parts has the first conductive type and is formed in the first well region.

2. The semiconductor device according to claim 1,
wherein, in the first direction, the second deep trench isolation part is arranged so as not to be formed between two transistors of the plurality of cutting adjacent cutting transistors.

3. The semiconductor device according to claim 1,
wherein, in the first direction, an outer dimension of each of the plurality of first power supply parts is smaller than an outer dimension of each of the plurality of first deep trench isolation parts.

4. The semiconductor device according to claim 3,
wherein, in plan view, the gate includes a plurality of first polycrystalline silicon layers arranged in the first direction,
wherein each of the plurality of first polycrystalline silicon layers extends in the second direction,
wherein a first silicide layer is formed on each of the plurality of first polycrystalline silicon layers, and
wherein the plurality of first polycrystalline silicon layers are electrically connected in parallel.

5. The semiconductor device according to claim 1,
wherein the semiconductor substrate has the first conductive type,
wherein a buried semiconductor layer of the second conductive type is formed between the first well region and the second main surface, and
wherein the second deep trench isolation part extends in a direction from the first main surface toward the second main surface and penetrates through the buried semiconductor layer.

6. The semiconductor device according to claim 1,
wherein each of the plurality of fuse elements is formed on a shallow trench isolation part formed in the semiconductor substrate at the first main surface, and
wherein a depth of the shallow trench isolation part from the first main surface is smaller than a depth of each of the plurality of first deep trench isolation parts from the first main surface.

7. The semiconductor device according to claim 6,
wherein each of the plurality of fuse elements includes a second polycrystalline silicon layer and a second silicide layer formed on the second polycrystalline silicon layer.

8. The semiconductor device according to claim 1,
wherein each of the plurality of fuse elements and a path from the drain to the source of each of the plurality of cutting transistors are connected in series between a power supply potential and a ground potential, and
wherein the first well region is connected to the ground potential via the plurality of first power supply parts.

9. The semiconductor device according to claim 1,
wherein the plurality of fuse circuits comprise a plurality of control circuits,
wherein each of the plurality of control circuits is connected to the gate of each of the plurality of cutting transistors,
wherein the plurality of control circuits comprise:
a plurality of first blocks comprising a plurality of first MISFETs of the second conductivity type;
a plurality of second power supply parts;
a plurality of second blocks comprising a plurality of second MISFETs of the first conductivity type; and
a plurality of third power supply parts,
wherein, in plan view, each of the plurality of second power supply parts integrally surrounds the plurality of first MISFETs included in each of the plurality of first blocks, and
wherein, in plan view, each of the plurality of third power supply parts integrally surrounds the plurality of second MISFETs included in each of the plurality of second blocks.

10. The semiconductor device according to claim 9,
wherein, in plan view, the plurality of first MISFETs included in the plurality of first blocks are formed in a second well region of the first conductivity type, wherein, in plan view, the plurality of second MISFETs included in the plurality of second blocks are formed in a third well region of the second conductivity type,
wherein each of the plurality of second power supply parts has the first conductivity type and is formed in the second well region, and
wherein each of the plurality of third power supply parts has the second conductivity type and is formed in the third well region.

11. The semiconductor device according to claim 10,
wherein, in plan view, the plurality of second power supply parts are arranged in the first direction,
wherein, in plan view, the plurality of third power supply parts are arranged in the first direction,
wherein, in the second direction, the plurality of third power supply parts are adjacent to the plurality of second power supply parts, and
wherein, in plan view, the plurality of second power supply parts and the plurality of third power supply parts are integrally surrounded by the third deep trench isolation part.

12. The semiconductor device according to claim 11,
wherein the plurality of control circuits further comprise:
a plurality of third blocks comprising a plurality of third MISFETs of the second conductivity type;
a plurality of fourth power supply parts integrally surrounding the plurality of third MISFETs in plan view;
a plurality of fourth blocks comprising a plurality of fourth MISFETs of the first conductivity type; and
a plurality of fifth power supply parts integrally surrounding the plurality of fourth MISFETs in plan view,
wherein, in plan view, the plurality of third MISFETs included in the plurality of third blocks are formed in a fourth well region of the first conductivity type,
wherein, in plan view, the plurality of fourth MISFETs included in the plurality of fourth blocks are formed in a fifth well region of the second conductivity type,
wherein each of the plurality of fourth power supply parts has the first conductivity type and is formed in the fourth well region, and
wherein each of the plurality of fifth power supply parts has the second conductivity type and is formed in the fifth well region.

13. The semiconductor device according to claim 12,
wherein, in plan view, the plurality of fourth power supply parts are arranged in the first direction,
wherein, in plan view, the plurality of fifth power supply parts are arranged in the first direction, and
wherein, in plan view, the plurality of second power supply parts, the plurality of third power supply parts, the plurality of fourth power supply parts, and the plurality of fifth power supply parts are integrally surrounded by the third deep trench isolation part.

14. The semiconductor device according to claim 13,
wherein, in the second direction, the second deep trench isolation part is arranged between the plurality of first deep trench isolation parts and the third deep trench isolation part.

15. The semiconductor device according to claim 9,
wherein the plurality of fuse circuits comprise a plurality of decision circuits,
wherein each of the plurality of decision circuits is connected in parallel to each of the plurality of fuse elements,
wherein the plurality of decision circuits comprise:
a plurality of fifth blocks comprising a plurality of fifth MISFETs of the second conductivity type; and
a plurality of sixth power supply parts,
wherein, in plan view, the plurality of fifth MISFETs included in the plurality of fifth blocks are formed in a sixth well region of the first conductivity type,
wherein, in plan view, each of the plurality of sixth power supply parts surrounds the plurality of fifth MISFETs included in each of the plurality of fifth blocks, and
wherein each of the plurality of sixth power supply parts has the first conductivity type and is formed in the sixth well region.

16. The semiconductor device according to claim 15,
wherein, in plan view, the plurality of sixth power supply parts are arranged in the first direction, and
wherein, in plan view, the plurality of sixth power supply parts are integrally surrounded by a fourth deep trench isolation part.

17. The semiconductor device according to claim 16,
wherein, in the second direction, the plurality of first deep trench isolation parts are arranged between the second deep trench isolation part and the fourth deep trench isolation part.

18. The semiconductor device according to claim 9,
wherein the plurality of control circuits comprise a (m−1)-th control circuit and an m-th control circuit adjacent to each other in the first direction,
wherein, in the first direction, each of the plurality of first blocks and each of the plurality of second blocks are alternately arranged, and wherein in one of the plurality of first blocks and one of the plurality of second blocks adjacent to each other in the first direction among the plurality of first blocks and the plurality of second blocks, a part of the plurality of second MISFETs is connected to the m-th control circuit, another part of the plurality of second MISFETs is connected to the (m−1)-th control circuit, and a part of the plurality of first MISFETs is connected to the (m−1)-th control circuit.

19. The semiconductor device according to claim 18,
wherein, in plan view, the plurality of first MISFETs included in each of the plurality of first blocks are formed in a seventh well region of the first conductivity type,
wherein, in plan view, the plurality of second MISFETs included in each of the plurality of second blocks are formed in an eighth well region of the second conductivity type,
wherein each of the plurality of second power supply parts has the first conductivity type and is formed in the seventh well region, and
wherein each of the plurality of third power supply parts has the second conductivity type and is formed in the eighth well region.
